(19) United States
(12) Patent Application Publication
(10) Pub. No.: US 2025/0254788 A1
(43) Pub. Date: Aug. 7, 2025

(54) IN-LINE CAPACITOR MODULE

(71) Applicant: NOKIA SOLUTIONS AND NETWORKS OY, Espoo (FI)

(72) Inventors: Daniel Fazari, Kanata (CA); Alex Chan, Ottawa (CA); Paul Brown, Wakefield (CA); Tom Stein, Kanata (CA)

(21) Appl. No.: 18/433,841

(22) Filed: Feb. 6, 2024

(51) Int. Cl. H05K 1/02; H01R 12/55; H05K 1/11; H05K 3/42

(52) U.S. Cl. CPC H05K 1/0231; H01R 12/55; H05K 1/115; H05K 3/429; H05K 2201/09163; H05K 2201/095; H05K 2201/10734

(57) ABSTRACT

An electronic product includes a first printed circuit board (PCB) having one or more electronic components disposed thereon, a second PCB having castellated vias on a first edge thereof, and further having one or more capacitors disposed thereon, wherein the castellated vias on the first edge of the second PCB are mechanically and electrically coupled to the first PCB. The second PCB may be attached to the first PCB such that the second PCB is nominally orthogonal to the first PCB. The one or more capacitors may be disposed on a first side of the second PCB, or on the first and second sides of the second PCB. The capacitors may be attached to the second PCB by surface mount technology (SMT), and the second PCB may be attached to the first PCB at the vertically-oriented castellated vias by SMT.

### FIELD OF THE DISCLOSURE

Various illustrative embodiments disclosed herein relate to providing decoupling capacitance for electronic products or systems.

### BACKGROUND

It is common in electronic products and systems, including those implemented with integrated circuits and printed circuit boards, to provide decoupling capacitors. Decoupling capacitors are useful for, among other things, reducing noise or interference that may adversely affect the performance of an electronic product or system.

### SUMMARY

A summary of various illustrative embodiments is presented below.

Various illustrative embodiments relate to electronic products. In one illustrative embodiment, an electronic product includes a first printed circuit board (PCB) having one or more electronic components disposed thereon; a second PCB having castellated vias on a first edge thereof, and further having one or more capacitors disposed thereon, wherein the castellated vias on the first edge of the second PCB are mechanically and electrically coupled to the first PCB, and the second PCB is nominally orthogonal to the first PCB.

In some embodiments, the one or more electronic components comprise at least one integrated circuit, and at least one surface-mount capacitor is disposed on the second PCB.

In some embodiments, the one or more capacitors are attached to a first side of the second PCB.

In some embodiments, at least a first one of the one or more capacitors is attached to a first side of the second PCB, and at least a second one of the one or more capacitors is attached to a second, opposite side, of the second PCB.

In some embodiments, the first one of the one or more capacitors and the second one of the one or more capacitors are coupled to electrically conductive material disposed on or in the first PCB.

In some embodiments, a first one of the one or more capacitors is a two terminal device having a first terminal coupled to a first power plane on the first PCB, and having a second terminal coupled to a first ground plane on the first PCB.

In some embodiments, a second one of the one or more capacitors is a two terminal device having a first terminal coupled to a second power plane on the first PCB, and having a second terminal coupled to a second ground plane on the first PCB.

In some embodiments, at least two of the one or more capacitors are coupled in parallel.

In some embodiments, a first one of the one or more capacitors has a first capacitance, a second one of the one or more capacitors has a second capacitance, and the first capacitance is different from the second capacitance.

In some embodiments, a first one of the one or more electronic components is an integrated circuit electrically coupled to the first PCB by a ball grid array package.

In another illustrative embodiment, an electronic product includes a first substrate having a plurality of integrated circuits coupled thereto, and further having a first power supply plane and a second power supply plane; and a second substrate having a plurality of capacitors coupled thereto, and further having a plurality of castellated vias disposed at an edge thereof; wherein the second substrate is coupled to the first substrate such that each capacitor of the plurality of capacitors is coupled to the first power supply plane and the second power supply plane, and the second substrate and the first substrate are nominally orthogonal to each other, and the plurality of castellated vias are vertically adjacent to the first substrate.

In some embodiments, at least one of the plurality of integrated circuits includes a ball grid array package, and the plurality of capacitors are surface-mount capacitors.

In some embodiments, a first capacitor of the plurality of capacitors has a first nominal capacitance, a second capacitor of the plurality of capacitors has a second nominal capacitance, and the first nominal capacitance is greater than the second nominal capacitance.

In some embodiments, a first portion of the plurality of capacitors is disposed on a first side of the second substrate, and a second portion of the plurality of capacitors is disposed on a second side of the second substrate.

In some embodiments, the first substrate comprises a multi-layer printed circuit board, and the plurality of capacitors are surface-mount capacitors.

In a further illustrative embodiment, an apparatus includes a first printed circuit board (PCB) having a plurality of components attached thereto, at least one of the components being attached to the first PCB by a ball grid array package; a second PCB having a plurality of surface-mount capacitors attached thereto, and further having a first edge comprising a plurality of castellated vias, wherein the first PCB and the second PCB are attached to each other such that the first PCB and the second PCB are nominally orthogonal, and the plurality of castellated vias are vertically adjacent the first PCB.

In some embodiments, the plurality of surface-mount capacitors are attached to a first side of the second PCB.

In some embodiments, the second PCB is a two-sided PCB, a first portion of the plurality of surface-mount capacitors are attached to a first side of the two-sided PCB, and a second portion of the plurality of surface-mount capacitors are attached to a second side of the second PCB.

In some embodiments, a first portion of the plurality of surface-mount capacitors have a first nominal capacitance.

In some embodiments, a second portion of the plurality of surface-mount capacitors have a second nominal capacitance, the second nominal capacitance being greater than the first nominal capacitance.

### BRIEF DESCRIPTION OF DRAWINGS

To facilitate a better understanding of various illustrative embodiments, reference is made to the accompanying drawings, wherein:

FIG. 1A is a cross-sectional view of a portion of an illustrative multi-layer printed circuit board (PCB) having a plurality of conductive inner layers, and a plurality of plated-through-hole vias;

FIG. 1B is a top view of a portion of an illustrative PCB showing a surface-mounted component, plated-through-hole vias, and signal traces;

FIG. 2A is a top view of a portion of a PCB showing a row of plated-through-hole vias;

FIG. 2B is a top view of a portion of a PCB showing a row of plated-through-hole vias, and a routing tool removing a portion of the PCB along with corresponding portions of the plated-through-hole vias to form castellated vias;

FIG. 3A is a perspective view of a portion of a PCB showing a plurality of castellated vias;

FIG. 3B is a top view of a portion of a PCB showing castellated vias at a first edge thereof;

FIG. 4 is a perspective view of a PCB having a plurality of capacitors attached thereto, and a plurality of castellated vias at a first edge thereof;

FIG. 5A is a cross-sectional view of an assembly having a first PCB having a predetermined connection point, and electronic components attached thereto, a second PCB having capacitors attached to a first side thereof and castellated vias at a first edge thereof, the second PCB nominally orthogonal to the first PCB, and the second PCB attached to the first PCB by the castellated vias of the vertically-oriented second PCB;

FIG. 5B is a cross-sectional view of an assembly, similar to that of FIG. 5A, except that the second PCB is a double-sided PCB and has capacitors attached to both its first side and its second side; and

FIG. 6 is a flow diagram of a method in accordance with this disclosure.

To facilitate understanding, identical reference numerals have been used in some places to designate elements having substantially the same or similar structure and/or substantially the same or similar function.

### DETAILED DESCRIPTION

Various aspects of the disclosure are described more fully herein with reference to the accompanying drawings. This disclosure may, however, be embodied in many different forms and should not be construed as limited to any specific structure or function presented throughout this disclosure. Rather, these aspects are provided so that this disclosure will be thorough and complete, and will fully convey the scope of the disclosure to those skilled in the art. Based on the teachings herein one skilled in the art should appreciate that the scope of the disclosure is intended to cover any aspect of the disclosure disclosed herein, whether implemented independently of, or combined with any other aspect of the disclosure. For example, an apparatus may be implemented, or a method may be practiced using any number of the aspects set forth herein. In addition, the scope of the disclosure is intended to cover such an apparatus or method which is practiced using other structure, functionality, or structure and functionality in addition to or other than the various aspects of the disclosure set forth herein. It should be understood that any aspect of this disclosure may be embodied by one or more elements of a claim.

A recognized issue for the operation of electronic products is the maintenance of stable power supply voltages. Another such issue is the need to reduce high-frequency noise. The reduction of signal coupling and improving of signal integrity are also recognized as issues that can affect circuit performance.

One of the ways of alleviating the above-described issues is by including one or more decoupling capacitors in the design of electronic products. In some instances, decoupling capacitors are sometimes referred to as bypass capacitors. Selecting the magnitude of the capacitance of the decoupling capacitors may depend on the specific requirements of the circuit, product, or system, including but not limited to, the frequency of operation. The physical placement of a decoupling capacitor, i.e., the location of the decoupling capacitor relative to an integrated circuit may impact the effectiveness of that decoupling capacitor. Typically, decoupling capacitors are placed close to the power pins of an integrated circuit to be most effective.

Unfortunately, various advances in other aspects of electronic product design and manufacturing have created challenges to achieving the best physical placement of decoupling capacitors. For example, surface area limitations proximate to ball grid array (BGA) integrated circuits limit the amount of decoupling capacitors that can be placed directly on a given printed circuit board. And yet, increased switching speeds require greater amounts of decoupling capacitance. Additionally, increases in the pin-count of BGAs, which results in more board area being used by the BGA, and decreases in the spacing of BGA pads, both limit the area available on a printed circuit board for deploying decoupling capacitors.

Further, over the past few decades, the trend toward miniaturization, i.e., increased density, in electronic and mechanical design has driven the need to put more and more components in small, confined areas. Consequently, discrete component sizes for capacitors and resistors have decreased significantly over that time. For example, in the past, 0805 package sizes for components were used on printed circuit boards, but it is now common to use 01005 package sizes. 0805 refers to a package size of 0.08×0.05 inches (i.e., about 2×1.3 mm); and 01005 refers to a package size of 0.016×0.008 inches (i.e., about 0.4×0.2 mm).

With the above-mentioned decrease in discrete component size, the amount of capacitance contained in a such a small body has also decreased. And, the reduction in the physical size of these components has further resulted in undesirable manufacturing constraints because of the inherent accuracy limitations of pick-and-place assembly equipment, which is used to populate printed circuit boards. Robotic placement, such as by pick-and-place equipment, of many discrete components (e.g., capacitors, resistors) in very close proximity to each other is difficult to perform. In other words, it has become more difficult to provide the desired amount of capacitance for decoupling at the desired location, relative to integrated circuits on a substrate such as a printed circuit board.

Various embodiments in accordance with this disclosure may provide the desired amount of capacitance for decoupling at the desired location, relative to an active electrical component such as, but not limited to, an integrated circuit. Various embodiments may provide additional decoupling capacitance for components on a main PCB by attaching a daughter board having a plurality of capacitors installed on one or both sides thereof. The daughter board may be attached to the main PCB such that it extends vertically away from the main PCB, and in some embodiments the daughter board is nominally orthogonal to the main PCB. And, in order to use a relatively small footprint on the main PCB, various embodiments mount the daughter board to the main PCB by way of a vertically-oriented castellated-via edge connector. In various embodiments the castellated-via edge connector may be attached to the main PCB by surface-mount technology.

An illustrative method, in accordance with this disclosure, provides a nominally orthogonal daughterboard for installing capacitors on its sides to solve PCB space limitations with regard to decoupling capacitors. A relatively small daughter board may be mounted at a nominally right angle to a first major surface of a main PCB thereby providing additional area which may be populated with, for example, surface-mount capacitors, while maintaining proximity to active circuitry for which decoupling capacitance is relevant. The daughter board may be populated on one of its major surfaces, or both of its major surfaces, with capacitors, such as surface-mount capacitors. In order to reduce the footprint of the daughter board on the main PCB, the daughter board is mechanically and electrically attached to the main PCB by way of conductive connection points disposed on an edge of the daughter board. The mechanical and electrical attaching process may include soldering. One type of conductive connection point on the edge of the daughter board may be realized by way of castellated via technology that takes advantage of standard manufacturing processes to yield a unique connector structure. During the process of mechanically and electrically attaching the daughter board to the main PCB by soldering, the daughter board may be held at a nominally right angle to the main PCB by a fixture. The soldering of this assembly operation, in accordance with this disclosure, may be achieved by surface-mount technology (SMT) soldering processes.

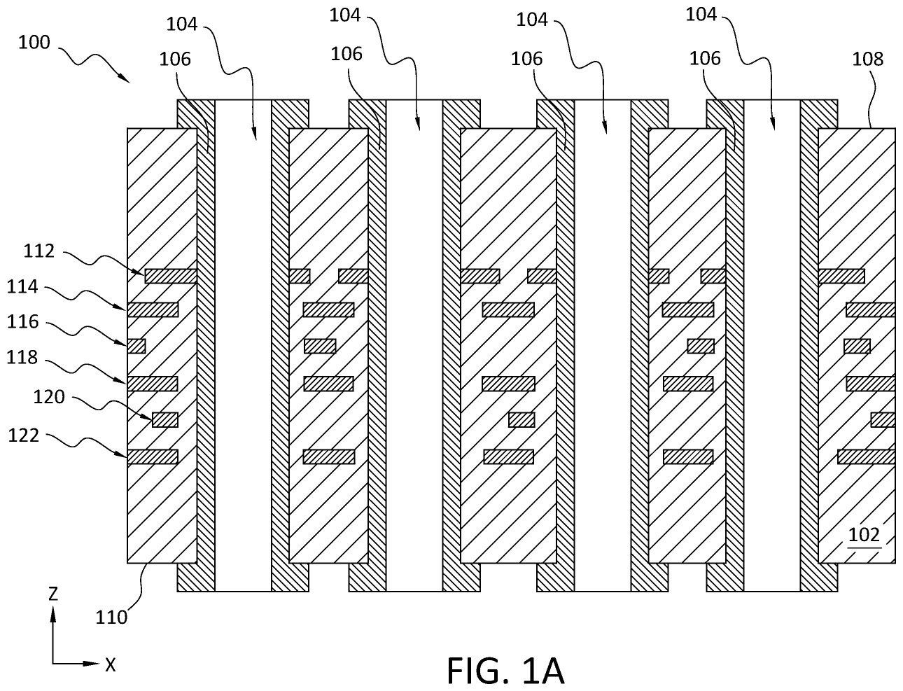

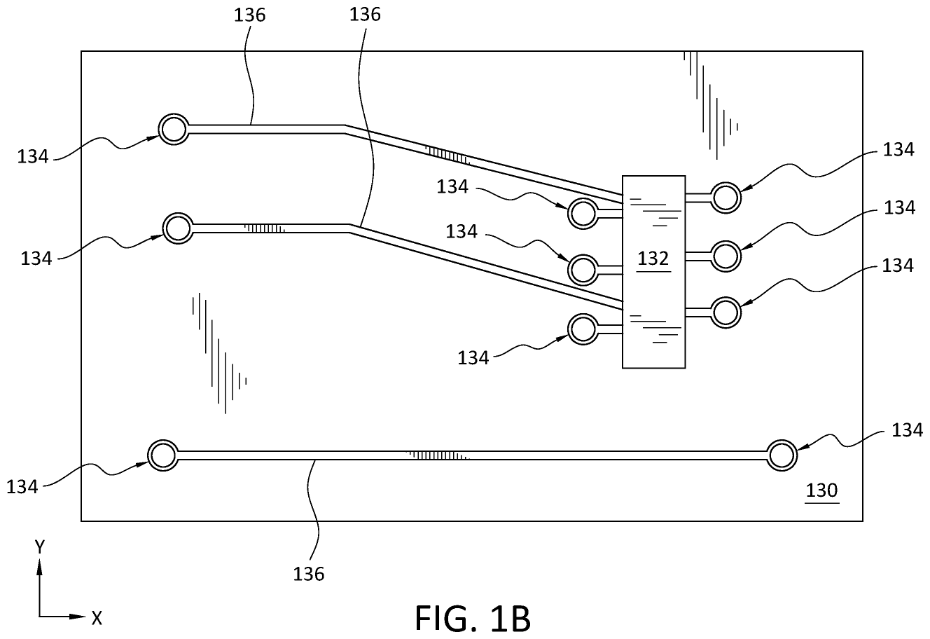

FIGS. 1A-1B illustrate a cross-section and a top view of generic multi-layer PCBs.

FIG. 1A is provided as an example of a multi-layer PCB. More particularly, FIG. 1A is a cross-sectional view of a portion of an illustrative multi-layer printed circuit board (PCB) 100 including a substrate 102 having a plurality of plated-through-hole vias 104 each having a conductive barrel 106, and a plurality of conductive inner layers 112, 114, 116, 118, 120, 122.

FIG. 1B is also provided as an example of a PCB. More particularly, FIG. 1B is a top view of a portion of an illustrative PCB 130 showing a surface-mounted component 132, plated-through-hole vias 134, and signal traces 136. It will be understood that this figure is only for illustration purposes, and is in no way limiting on the possible arrangements or layout of components, plated-through-hole vias, or signal traces.

As PCBs, such as but not limited to those illustrated in FIGS. 1A-1B, have become more densely packed with components, including components attached to the PCB by, for example, ball grid array (BGA) packages, it has become increasingly difficult to provide decoupling capacitors close by to such components on the PCB.

Various illustrative embodiments, in accordance with this disclosure, overcome the issue of providing sufficient decoupling capacitance to components disposed on a PCB without consuming significant area on the PCB. Various illustrative embodiments provide a daughter board for attachment to a main PCB, where the daughter board consumes an area of the main PCB that is small relative to the amount of capacitance that it provides. A daughter board, in accordance with this disclosure, may be attached, or mounted, to the main PCB by, for example, surface-mount technology. A daughter board, in accordance with this disclosure, may be mounted such that the daughter board and the main PCB are nominally orthogonal to each other. The daughter board may be a single-sided PCB, a double-sided PCB, or a multi-layer PCB.

In some embodiments, the daughter board includes capacitors surface-mounted to a first side of a single-sided PCB. In some embodiments, the daughter board includes capacitors surface-mounted to a first side only of a double-sided PCB. In some embodiments, the daughter board includes capacitors surface-mounted to a first side and a second side of a double-sided PCB.

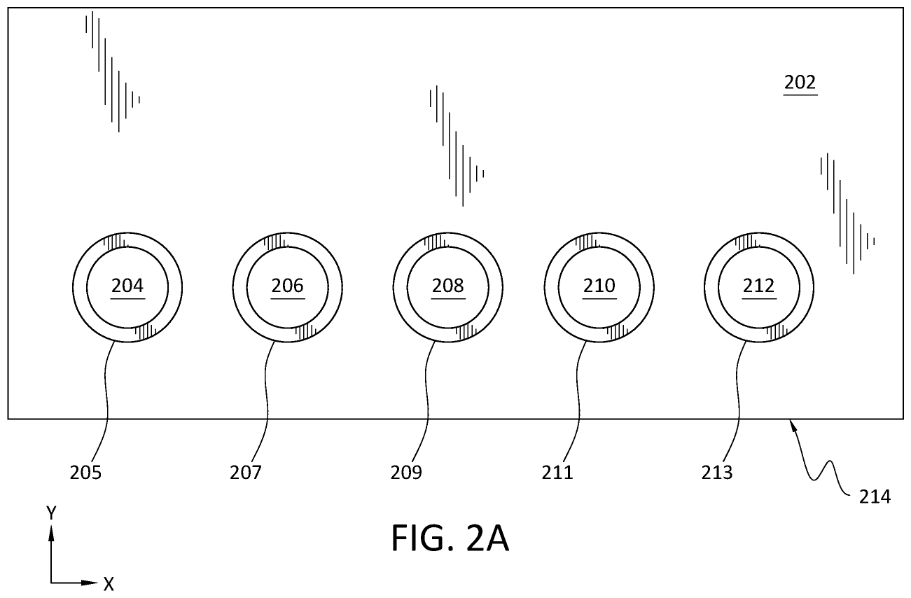

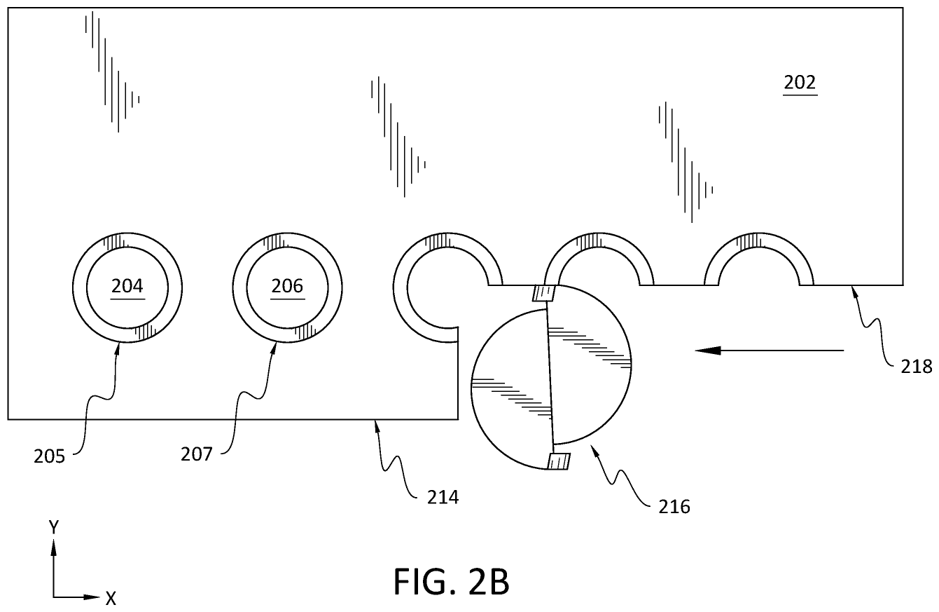

FIGS. 2A-2B illustrate the formation of castellated vias at a first edge of a PCB, such as the aforementioned daughter board.

FIG. 2A is a top view of a portion of a PCB 202 showing plated-through-hole vias 204, 206, 208, 210, 212. Each plated-through-hole via 204, 206, 208, 210, 212, has a respective conductive barrel 205, 207, 209, 211, 213. Plated-through-hole vias 204, 206, 208, 210, 212, are arranged in a row near a first edge 214 of PCB 202. Forming plated-through-hole via 204, 206, 208, 210, 212, near first edge 214 facilitates the formation of castellated vias as can be seen in FIG. 2B.

FIG. 2B is a top view of a portion of PCB 202 showing a row of plated-through-hole vias, and a routing tool 216 removing a portion of PCB 202 along with corresponding portions of the plated-through-hole vias to form castellated vias, and a new first edge 218. In some embodiments, half of a plated-through-hole via is removed to form a castellated via. In other embodiments, more than half, or less than half of the plated-through-hole via is removed to form a castellated via. In accordance with this disclosure, first edge 218 having the castellated vias is used (as discussed below) to connect to another board, typically orthogonally.

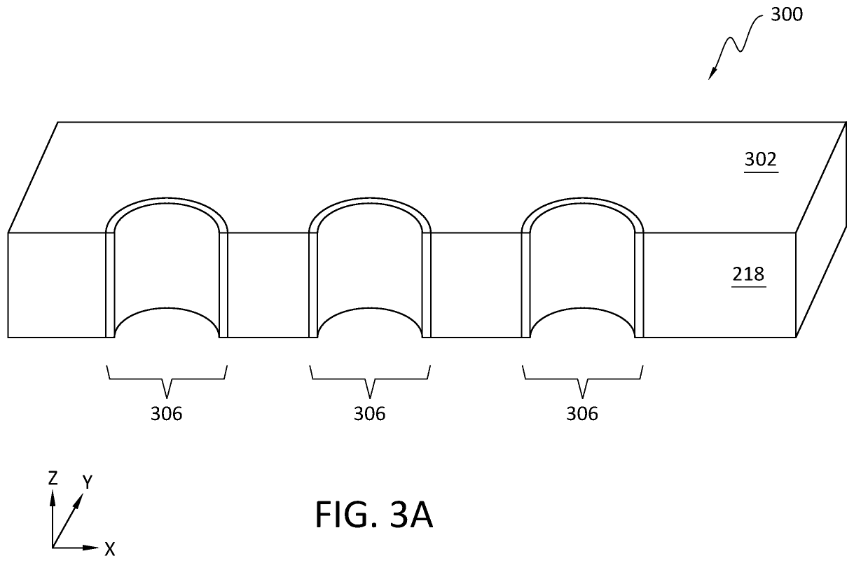

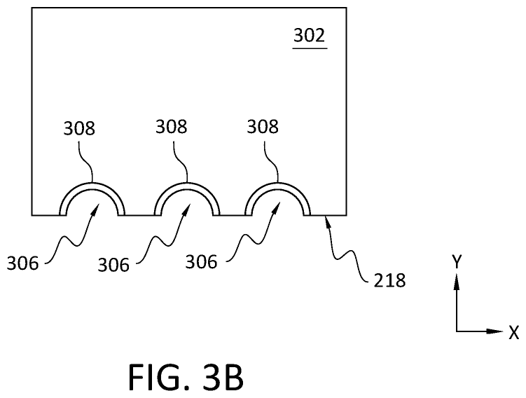

FIG. 3A is a perspective view of a portion of a PCB 300 having a top surface 302, a first edge 218, and a plurality of castellated vias 306. Castellated vias 306 are formed by routing, or edge-milling, the edge of a PCB having a set of plated-through-hole vias until a portion of each of the plated-through-holes of the set of plated-through-holes, for example but not limited to half, is removed. These castellated vias may be subsequently connected at nominally right angles to another PCB by surface mount technology.

FIG. 3B shows a top surface 302 of a portion of a PCB having castellated vias 306 at first edge 218. Each castellated via 306 includes a conductive portion 308. In this illustrative embodiment, each conductive portion 308 is formed from the conductive barrel of a plated-through-hole via (see FIG. 2B).

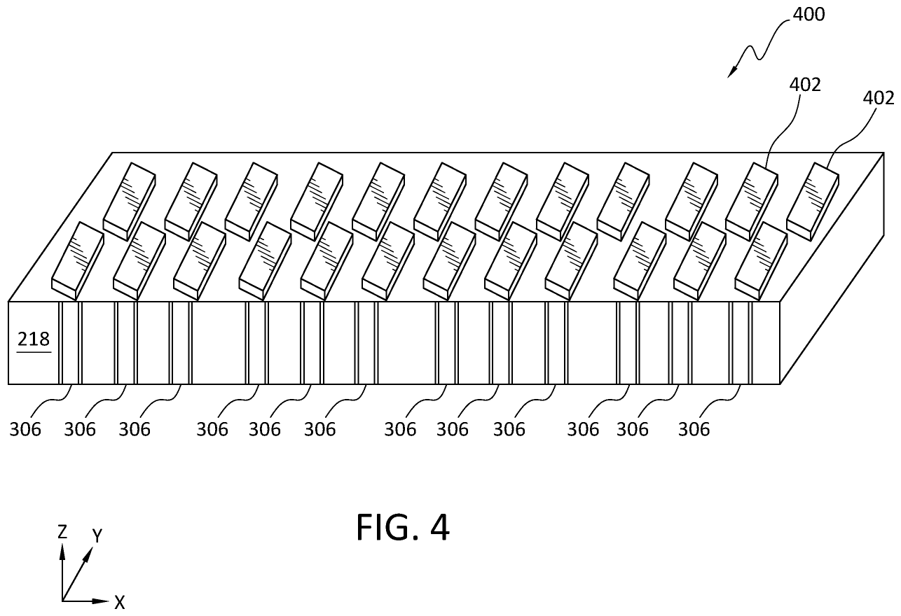

FIG. 4 is a perspective view of a PCB 400, in accordance with this disclosure, having a plurality of capacitors 402 attached thereto, and a plurality of castellated vias 306 at a first edge 218 thereof. In various embodiments, in accordance with this disclosure, PCB 400 may be referred to as a daughter board. As discussed below, a daughter board may be attached to a main PCB by, for example, soldering in accordance with surface-mount technology (SMT).

Still referring to FIG. 4, in this illustrative embodiment, capacitors 402 are attached to PCB 400 by surface-mount technology (including pick-and-place and surface-mount soldering). However, capacitors 402 may be attached to PCB 400 by any suitable means whereby electrical coupling to capacitors 402 is available by way of castellated vias 306. Typically, electrical paths from terminals of capacitors 402 to corresponding castellated vias are provided by signal traces on the daughter board. Those skilled in the art will recognize that capacitors are two-terminal devices. The number of capacitors 402 and the number of castellated vias 306 shown in FIG. 4 are for illustrative purposes. Those skilled in the art will appreciate that there may be more or fewer capacitors 402 than shown, and more or fewer castellated vias 306 than shown in any particular implementation in accordance with this disclosure. Further, in some embodiments, capacitors 402 may be disposed on a single side of the daughter board (single-sided implementation), while in other embodiments capacitors 402 may be disposed on a front side and a back side of the daughter board (double-sided implementation).

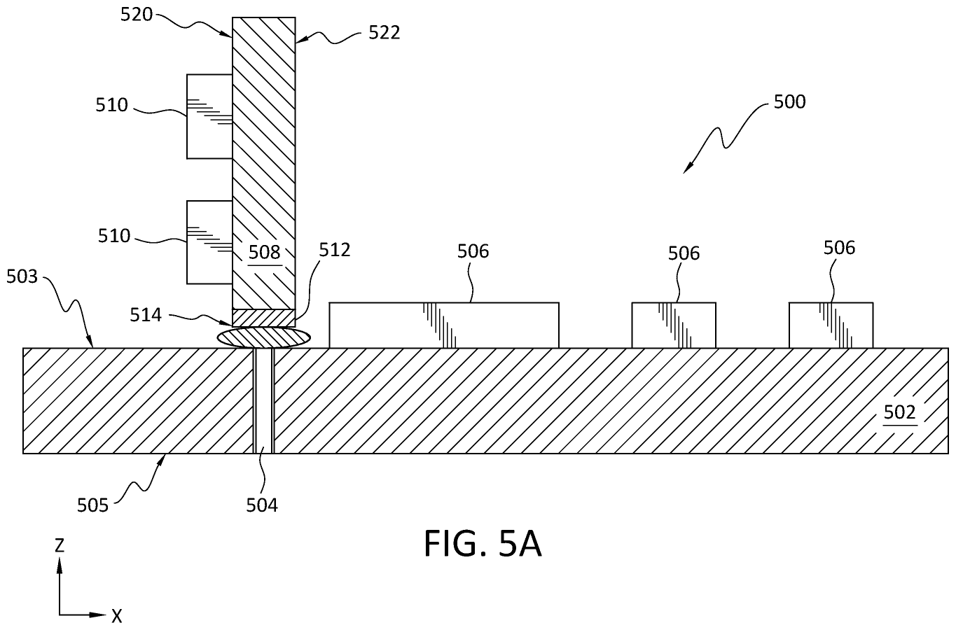

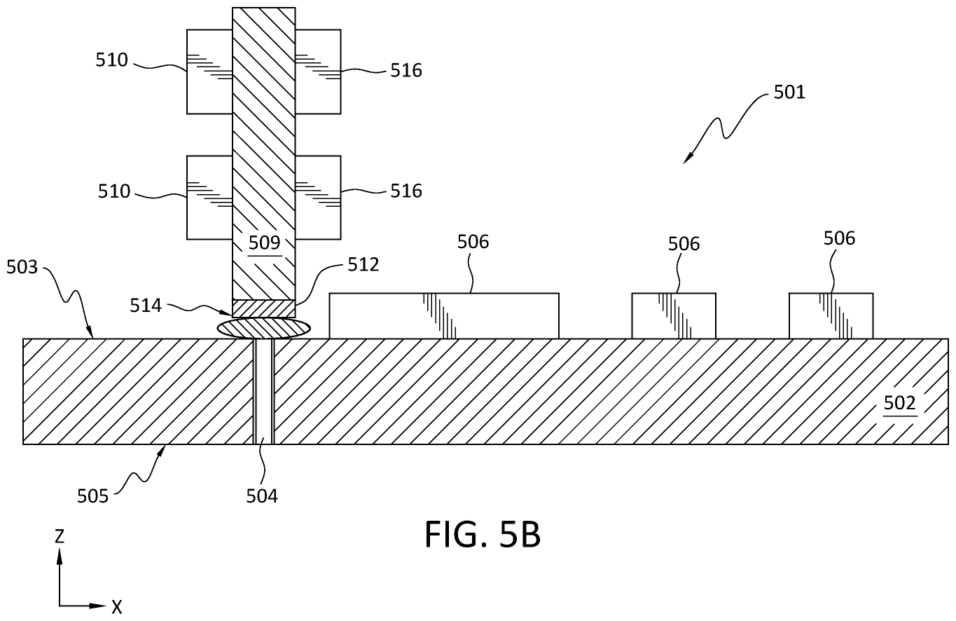

FIGS. 5A-5B each illustrate an assembly, in accordance with this disclosure, that has a main PCB and a daughter board, nominally orthogonal and attached to each other, where the daughter board is populated with at least surface-mount capacitors and the main PCB is populated with at least active circuitry.

FIG. 5A is a cross-sectional view of an assembly 500 including a first PCB 502 having a first major surface 503, a predetermined connection point 504, a second major surface 505, and a plurality of electronic components 506 attached thereto, a second PCB 508 having capacitors 510 attached to a first side thereof and castellated vias 512 at a first edge 514 thereof, the second PCB 508 nominally orthogonal to the first PCB 502, and attached to the first PCB by castellated vias 512 that are surface-mount soldered to the predetermined connection point 504 of first PCB 502. In other words, the second PCB may be attached to the predetermined connection point 504 of first PCB 502 by way of the vertically-oriented castellated vias 512 attached by SMT. Second PCB 508 has a first side 520 and a second side 522. Electronic components 506 typically include active circuitry, such as that found on integrated circuits. Such integrated circuits may benefit from decoupling capacitance. The predetermined connection points are generally chosen so as to provide decoupling capacitance as close as is practical to the electronic components that benefit from the decoupling capacitance.

In some embodiments there may be more than one orthogonally-oriented daughter board attached to the main PCB at corresponding predetermined connection points. In this way, needed decoupling capacitance may be provided at different locations on a main PCB without using more area of the main PCB than is available for decoupling capacitors.

FIG. 5B is a cross-sectional view of an assembly 501, similar to that of FIG. 5A, except that the second PCB is a double-sided PCB 509 and has capacitors 510 attached to its first side and capacitors 516 attached to its second side.

An illustrative method, in accordance with this disclosure, of providing decoupling capacitance to electronic components on a PCB while consuming very little area on the PCB includes providing a daughter board containing a plurality of capacitors and attaching the daughter board to a main PCB. Those skilled in the art, will recognize that the number of capacitors, the specific amount of capacitance, and the type of capacitors selected, are design choices based on well-understood principles of electrical engineering.

In some methods in accordance with this disclosure, the first PCB 502 has a first major surface 503 and a second major surface 505, and may be, but is not required to be, a multi-layer PCB. As shown in FIG. 5A, daughter board 508 has a first side 520, a second side 522, and a first edge 514. Daughter board 508 may be a single-sided PCB, a double-sided PCB, or a multi-layer PCB. Daughter board 508 has a plurality of castellated vias 512 disposed along its first edge 514. In accordance with this disclosure, daughter board 508 has capacitors disposed on the first side 520 of thereof. The daughter board 508 and the main PCB 502 may be connected by bringing the castellated vias 512 of the daughter board's first edge 514 proximate to a predetermined connection location 504 on the first major surface 503 of the first PCB 502. The daughter board 508 may be oriented with respect to the first PCB 502 such that the daughter board 508 and the first PCB 502 are nominally orthogonal to each other. The castellated vias 512 of the daughter board 508 may be soldered to the predetermined connection point 504 on the first PCB 502 by a process such as, but not limited to, SMT soldering. In some embodiments, a fixture may be used to hold daughter board 508/509 in place during the surface-mount soldering operation. As noted above, FIG. 5B is similar to FIG. 5A but illustrates an embodiment in which the daughter board 509 has capacitors 510 attached to its first side and capacitors 516 attached to its second side. The number of capacitors shown in FIGS. 5A and 5B are for illustrative purposes only, and any particular embodiment may have more or fewer capacitors. Similarly, in some embodiments the number of capacitors attached to the first side of daughter board 509 may be different from the number of capacitors attached to the second side of daughter board 509.

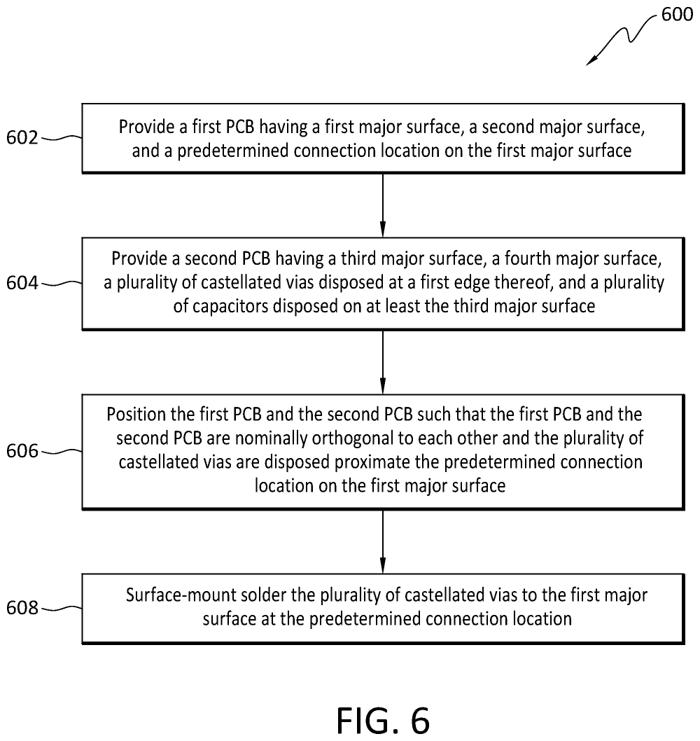

FIG. 6 is a flow diagram of a method 600 in accordance with this disclosure. More particularly, method 600 includes providing 602 a first PCB having a first major surface, a second major surface, and a predetermined connection location on the first major surface, and providing 604 a second PCB having a third major surface, a fourth major surface, a plurality of castellated vias disposed at a first edge thereof, and a plurality of capacitors disposed on at least the third major surface. The plurality of capacitors may be, but are not required to be, surface-mount capacitors. Method 600 further includes positioning 606 the first PCB and the second PCB such that the first PCB and the second PCB are nominally orthogonal to each other and the plurality of castellated vias are disposed proximate the predetermined connection location on the first major surface. Method 600 still further includes surface-mount soldering 608 the plurality of castellated vias to the first major surface at the predetermined connection location.

The foregoing disclosure provides illustration and description, but is not intended to be exhaustive or to limit the aspects to the precise form disclosed. Modifications and variations may be made in view of the above disclosure or may be acquired from practice of the aspects.

Unless stated otherwise, terms such as “first” and “second” are used to arbitrarily distinguish between the elements such terms describe. Thus, these terms are not necessarily intended to indicate temporal or other prioritization of such elements.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (e.g., rotated 90 degrees or at other orientations) and the spatially relative descriptors used herein may likewise be interpreted accordingly.

Various embodiments of this disclosure may include printed circuit boards. Many modern electronic products are implemented with printed circuit boards such as, but not limited to, multi-layer printed circuit boards. A printed circuit board (PCB) serves as a platform for supporting and connecting various active and/or passive electronic components such as, but not limited to, integrated circuits, transistors, diodes, resistors, capacitors, and inductors. That is, a PCB provides mechanical support for, and electrically conductive interconnect pathways between, the various components disposed on the PCB.

A PCB has a substrate, or base material, which may be made of, for example, fiberglass-reinforced epoxy laminate, but PCBs are not limited to this material. In order to form electrically conductive pathways, an electrically conductive material, such as a copper foil for example, is formed on the substrate. The electrically conductive material is then etched to from the desired pattern of conductive pathways. When the PCB is populated with components and operated, these conductive pathways may carry, for example, electrical signals. Such conductive pathways may also be referred to as “traces.”

In general, PCBs may have a single-sided, double-sided, or multi-layer configuration. A single-sided PCB has electrically conductive pathways on one side thereof. A double-sided PCB has electrically conductive pathways on each of its two sides. A multi-layer PCB includes multiple layers of electrically conductive material separated by insulation layers.

PCBs may have pads and/or lands to accommodate the placement and attachment of components thereto. Pads may be used, for example, for through-hole components. Lands may be used, for example, for surface-mount components.

PCBs in general, and multi-layer PCBs in particular may include plated-through-holes to provide electrical connection between different layers of the PCB. The plated-through-holes may be referred to herein as plated-through-hole vias, or simply as vias. The plated-through-holes typically traverse the entire thickness of the PCB, thereby providing an electrical path from a front side to a back side of the PCB. In such an arrangement, the length of the plated through hole via is at least as long as the PCB is thick.

As noted above, a plated-through-hole via may provide an electrical connection between, for example, signal traces on different layers of a multi-layer PCB. In many instances, the signal traces to be connected by the plated-through-hole via are not separated by the thickness of the entire multi-layer PCB. That is, in many instances the separation of the signal traces to be connected is less than the thickness of the PCB. However, since the plated-through-hole via runs through the entire thickness of the PCB, there will be a portion of the plated-through-hole via that extends past the last layer to be connected by the plated-through-hole via.

The foregoing disclosure provides illustration and description, but is not intended to be exhaustive or to limit the aspects to the precise form disclosed. Modifications and variations may be made in light of the above disclosure or may be acquired from practice of the aspects.

As used herein, the term “vertical/vertically” means nominally orthogonal to the surface of the object being referenced.

As used herein, the term “nominal/nominally” refers to a desired, or target, value of a characteristic or parameter for a component or a process operation, set during the design phase of a product or a process, together with a range of values above and/or below the desired value. The range of values can be due to slight variations in manufacturing processes or tolerances.

As used herein, the term “about” indicates the value of a given quantity may vary from its nominal value based on, for example, various manufacturing tolerances. By way of example, and not limitation, the term “about” may indicate the cited value of a given quantity may vary within, for example, 1-30% of the value (e.g., ±0.5%, ±1%, ±5%, ±10%, ±20%, or ±30% of the value). Specific ranges are provided herein when needed.

Unless stated otherwise, terms such as “first” and “second” are used to arbitrarily distinguish between the elements such terms describe. Thus, these terms are not necessarily intended to indicate temporal or other prioritization of such elements.

It should be appreciated by those skilled in the art that any block diagrams herein represent conceptual views of illustrative hardware embodying the principles of the aspects.

While each of the embodiments are described above in terms of their structural arrangements, it should be appreciated that the aspects also cover the associated methods of using the embodiments described above.

Even though particular combinations of features are recited in the claims and/or disclosed in the specification, these combinations are not intended to limit the disclosure of various aspects. In fact, many of these features may be combined in ways not specifically recited in the claims and/or disclosed in the specification. Although each dependent claim listed below may directly depend on only one claim, the disclosure of various aspects includes each dependent claim in combination with every other claim in the claim set. A phrase referring to “at least one of” a list of items refers to any combination of those items, including single members. As an example, “at least one of: a, b, or c” is intended to cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

No element, act, or instruction used herein should be construed as critical or essential unless explicitly described as such. Also, as used herein, the articles “a” and “an” are intended to include one or more items, and may be used interchangeably with “one or more.” Furthermore, as used herein, the terms “set” and “group” are intended to include one or more items (e.g., related items, unrelated items, a combination of related and unrelated items, and/or the like), and may be used interchangeably with “one or more.” Where only one item is intended, the phrase “only one” or similar language is used. Also, as used herein, the terms “has,” “have,” “having,” and/or the like are intended to be open-ended terms. Further, the phrase “based on” is intended to mean “based, at least in part, on” unless explicitly stated otherwise.

Although the various exemplary embodiments have been described in detail with particular reference to certain exemplary aspects thereof, it should be understood that the invention is capable of other embodiments and its details are capable of modifications in various obvious respects. As is readily apparent to those skilled in the art, variations and modifications can be affected while remaining within the spirit and scope of the invention. Accordingly, the foregoing disclosure, description, and figures are for illustrative purposes only and do not in any way limit the invention, which is defined only by the subjacent claims.

What is claimed is:

1. An electronic product, comprising:
a first printed circuit board (PCB) having one or more electronic components disposed thereon; and
a second PCB having castellated vias on a first edge thereof, and further having one or more capacitors disposed thereon,
wherein the castellated vias on the first edge of the second PCB are mechanically and electrically coupled to the first PCB, and
wherein the second PCB is nominally orthogonal to the first printed circuit board.

2. The electronic product of claim 1, wherein the one or more electronic components comprise at least one integrated circuit, and
wherein at least one surface-mount capacitor is disposed on the second PCB.

3. The electronic product of claim 1, wherein the one or more capacitors are attached to a first side of the second PCB.

4. The electronic product of claim 1, wherein at least a first one of the one or more capacitors is attached to a first side of the second PCB, and at least a second one of the one or more capacitors is attached to a second, opposite side, of the second PCB.

5. The electronic product of claim 4, wherein the first one of the one or more capacitors and the second one of the one or more capacitors are coupled to electrically conductive material disposed on or in the first PCB.

6. The electronic product of claim 1, wherein a first one of the one or more capacitors is a two terminal device having a first terminal coupled to a first power plane on the first PCB, and having a second terminal coupled to a first ground plane on the first PCB.

7. The electronic product of claim 6, wherein a second one of the one or more capacitors is a two terminal device having a first terminal coupled to a second power plane on the first PCB, and having a second terminal coupled to a second ground plane on the first PCB.

8. The electronic product of claim 1, wherein at least two of the one or more capacitors are coupled in parallel.

9. The electronic product of claim 1, wherein a first one of the one or more capacitors has a first capacitance, a second one of the one or more capacitors has a second capacitance, and the first capacitance is different from the second capacitance.

10. The electronic product of claim 1, wherein a first one of the one or more electronic components is an integrated circuit electrically coupled to the first PCB by a ball grid array package.

11. An electronic product, comprising:
a first substrate having a plurality of integrated circuits coupled thereto, and further having a first power supply plane and a second power supply plane; and
a second substrate having a plurality of capacitors coupled thereto, and further having a plurality of castellated vias disposed at an edge thereof,
wherein the second substrate is coupled to the first substrate such that each capacitor of the plurality of capacitors is coupled to the first power supply plane and the second power supply plane, and
wherein the second substrate and the first substrate are nominally orthogonal to each other, and the plurality of castellated vias are vertically adjacent to the first substrate.

12. The electronic product of claim 11, wherein at least one of the plurality of integrated circuits includes a ball grid array package, and
wherein the plurality of capacitors are surface-mount capacitors.

13. The electronic product of claim 11, wherein a first capacitor of the plurality of capacitors has a first nominal capacitance, a second capacitor of the plurality of capacitors has a second nominal capacitance, and the first nominal capacitance is greater than the second nominal capacitance.

14. The electronic product of claim 11, wherein a first portion of the plurality of capacitors is disposed on a first side of the second substrate, and a second portion of the plurality of capacitors is disposed on a second side of the second substrate.

15. The electronic product of claim 11, wherein the first substrate comprises a multi-layer printed circuit board, and the plurality of capacitors are surface-mount capacitors.

16. An apparatus, comprising:
a first printed circuit board (PCB) having a plurality of components attached thereto, at least one of the components being attached to the first PCB by a ball grid array package; and
a second PCB having a plurality of surface-mount capacitors attached thereto, and further having a first edge comprising a plurality of castellated vias,
wherein the first PCB and the second PCB are attached to each other such that the first PCB and the second PCB are nominally orthogonal, and the plurality of castellated vias are vertically adjacent to the first PCB.

17. The apparatus of claim 16, wherein the plurality of surface-mount capacitors are attached to a first side of the second PCB.

18. The apparatus of claim 16, wherein the second PCB is a two-sided PCB, a first portion of the plurality of surface-mount capacitors are attached to a first side of the two-sided PCB, and a second portion of the plurality of surface-mount capacitors are attached to a second side of the second PCB.

19. The apparatus of claim 16, wherein a first portion of the plurality of surface-mount capacitors have a first nominal capacitance.

20. The apparatus of claim 19, wherein a second portion of the plurality of surface-mount capacitors have a second nominal capacitance, the second nominal capacitance being greater than the first nominal capacitance.
